(19) United States
(12) Patent Application Publication
(10) Pub. No.: US 2011/0189828 A1
(43) Pub. Date: Aug. 4, 2011

(54) Method for forming silicon layer and method for manufacturing semiconductor device

(75) Inventors: Nobuyuki Sako, Tokyo (JP); Eiji Hasunuma, Tokyo (JP); Yuki Togashi, Tokyo (JP)

(73) Assignee: Elpida Memory, Inc., Tokyo (JP)

(21) Appl. No.: 12/926,836

(22) Filed: Dec. 13, 2010

(30) Foreign Application Priority Data
Dec. 21, 2009 (JP) 2009-288858

(51) Int. Cl. H01L 21/336; H01L 21/28

(52) U.S. Cl. 438/239; 438/514; 257/E21.158; 257/E21.409

(57) ABSTRACT

A silicon layer is formed on a silicon substrate by an epitaxial growth, and, then a surface of the silicon layer is oxidized. The surface of the silicon layer is cleaned, to remove foreign material generated on the surface of the silicon layer during the epitaxial growth.

This application is based upon and claims the benefit of priority from Japanese Patent Application No. 2009-288858, filed on Dec. 21, 2009, the disclosure of which is incorporated herein in its entirety by reference.

### TECHNICAL FIELD

The invention relates to a method for forming a silicon layer and a method for manufacturing a semiconductor device.

### BACKGROUND ART

In manufacturing a semiconductor device, a technique has been employed in which the silicon layer is formed on a silicon substrate by the epitaxial growth. For example, the technique has been used in forming source and drain electrodes in an elevated source and drain transistor (ESD transistor). Japanese Patent Laid-Open No. 2000-49348 discloses a semiconductor device including the transistor with such an elevated source and drain structure.

### SUMMARY OF THE INVENTION

In one embodiment, there is provided a method for forming a silicon layer, comprising:

forming a silicon layer on a silicon substrate by an epitaxial growth;

oxidizing a surface of the silicon layer; and cleaning the surface of the silicon layer.

In another embodiment, there is provided a method for manufacturing a semiconductor device, comprising:

forming a gate insulating film on a silicon substrate and forming a gate electrode layer including a gate electrode on the formed gate insulating film, and, then, forming a first side wall on a side wall of the gate electrode;

forming first and second silicon layers by an epitaxial growth, in first and second regions positioned in opposite sides which sandwiches the gate electrode layer and on the silicon substrate, each of the first and second silicon layers containing an impurity;

oxidizing surfaces of the first and second silicon layers;

cleaning the surfaces of the first and second silicon layers; and

forming source and drain regions in the silicon substrate so as to be in contact with the first and second silicon layers, respectively,

wherein the silicon substrate, the gate insulting film, the gate electrode, the first and second silicon layers and the source and drain regions form one transistor.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows an exemplary embodiment of a method for forming a silicon layer according to the invention;

FIG. 2 is a top view of an exemplary embodiment of a semiconductor device according to the invention; and

FIG. 3 to FIG. 13 are cross-sectional views of exemplary embodiments of a method for manufacturing a semiconductor device according to the invention.

In the drawings, numerals have the following meanings: 1, 11: transistor formation region, 2, 13: isolation oxide film region, 3, 14: gate electrode, 4, 15: side wall, 5, 16: silicon layer, 6: contact plug, 8: first region, second region, 12: gate insulating film, 14a: polysilicon film, 14b: tungsten nitride film, 14c: tungsten film, 14d: silicon nitride film, 16a: lower silicon layer, 16b: upper silicon layer, 17: foreign material, 18: oxide silicon film, 19: gate interlayer oxide silicon film, 20: diffusion layer, 21: silicon substrate, 22: silicon layer, 23: cohesive foreign material, 24: oxide silicon film, 31: contact hole, 32: contact plug, 40, 43, 44: insulating film, 41: bit line, 42: capacitor

### DETAILED DESCRIPTION OF THE REFERRED EMBODIMENTS

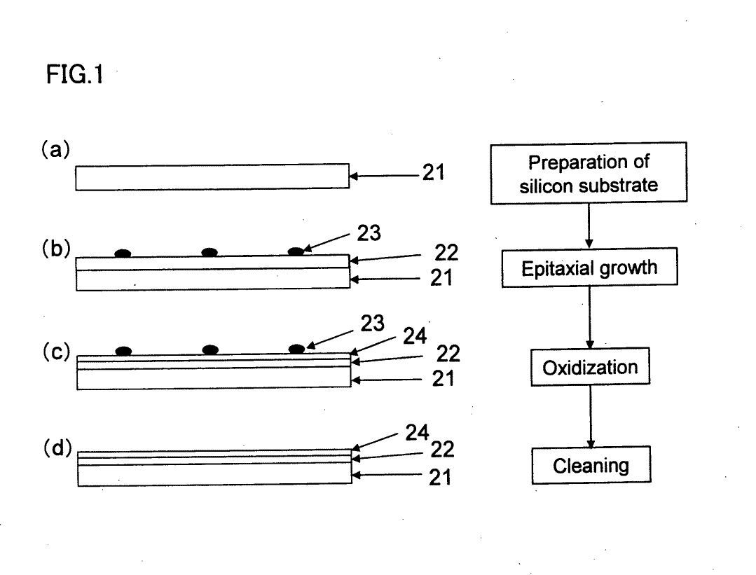

FIG. 1 shows one exemplary of a method for forming a silicon layer according to the invention. First, a silicon substrate 21 is prepared (FIG. 1 (a)), and, then, a silicon layer 22 is formed on the silicon substrate 21 by the epitaxial growth (FIG. 1 (b)). At this time, foreign material 23 appears on a surface of the silicon layer 22. Thereafter, a silicon oxide layer 24 is formed on the surface of the silicon layer 22 by performing an oxidization treatment of the surface of the silicon layer (FIG. 1 (c)). At this time, the foreign material 23 comes into being attached onto the silicon oxide layer 24. Next, the foreign material 23 is removed by performing a cleaning treatment (FIG. 1 (d)).

In this way, by oxidizing the surface of the silicon layer and, then, cleaning a surface of the resultant structure, the surface of the silicon layer can be prevented from being dissolved and the cohesive foreign material formed during the epitaxial growth can be removed. As a result, the silicon layer which has a clean surface and an uniform thickness can be obtained.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In addition, a description will be given by defining a surface in which semiconductor elements are formed as a front surface, and defining a surface opposite to the front surface as a rear surface, in a semiconductor substrate (wafer). Although in the below-described exemplary embodiments, only one through-hole electrode is shown in one semiconductor chip for purposes of illustration, two or more through-hole electrodes may be present in one semiconductor chip.

### First Exemplary Embodiment

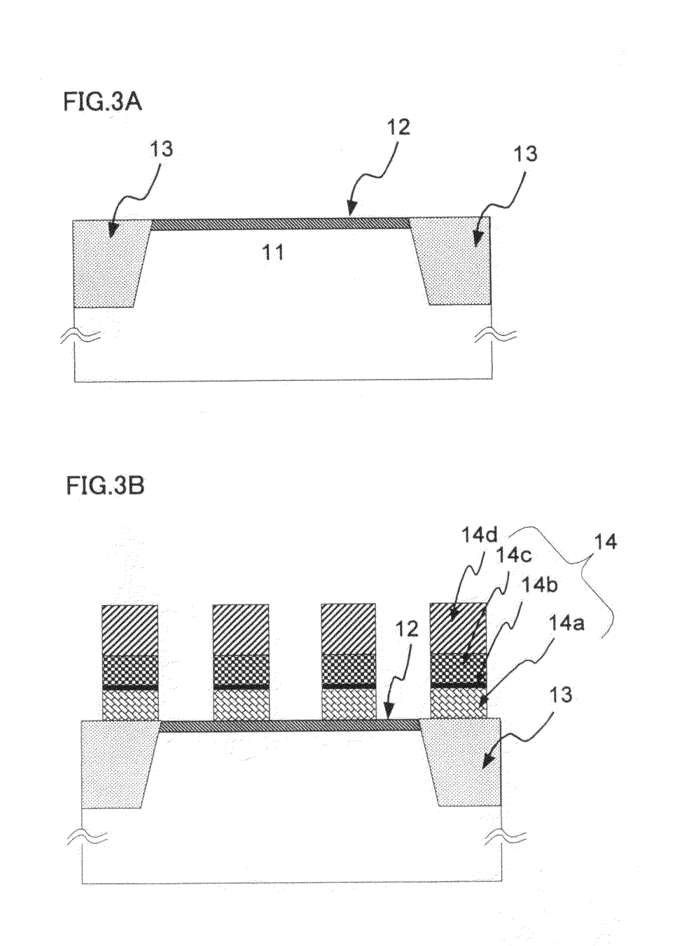

As shown in FIG. 3A, STI (Shallow Trench Isolation) is formed in a silicon substrate so that the silicon substrate is divided into transistor region 11 and trench isolation oxide film region 13. Then, gate insulating film 12 is formed on the surface of the silicon substrate using an oxidization method.

As shown in FIG. 3B, gate electrodes 14 are formed using a photolithography technique. Gate electrodes 14 have a stacked structure in which polysilicon film 14a, tungsten nitride film 14b, and tungsten film 14c are stacked in this order. In forming gate electrodes 14, polysilicon film 14a, tungsten nitride film 14b, tungsten film 14c, and silicon nitride film 14d are formed in this order on gate insulating film 12. Thereafter, a patterned photoresist is formed on silicon nitride film 14d. Then, silicon nitride film 14d is subjected to dry etching using the patterned photoresist as a mask, and, next, tungsten film 14c, tungsten nitride film 14b, and polysilicon film 14a are subjected to dry etching using the etched silicon nitride film 14d as a mask. This example is only one example of materials used for the gate electrode, and, thus, the materials used for the gate electrode of the invention are not limited to such materials.

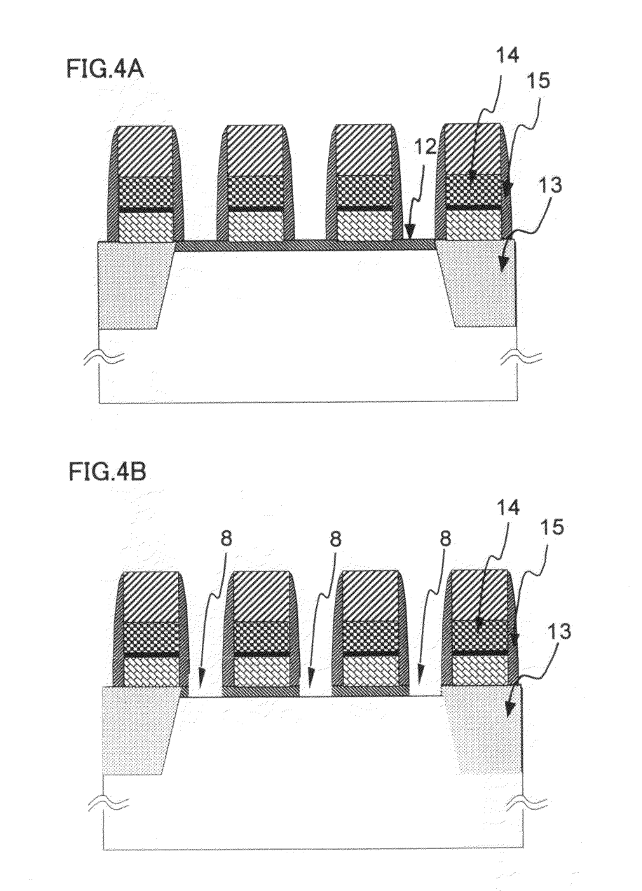

As shown in FIG. 4A, a silicon nitride film is formed on an entire surface of the resultant structure using a CVD method, and, then, is etched back by dry etching, so that first side walls 15 are formed on side walls of gate electrodes 14.

As shown in FIG. 4B, gate electrode 12, in regions at which the silicon layers will be deposited by the epitaxial growth, is removed by wet etching, so that in the regions, to expose the silicon substrate.

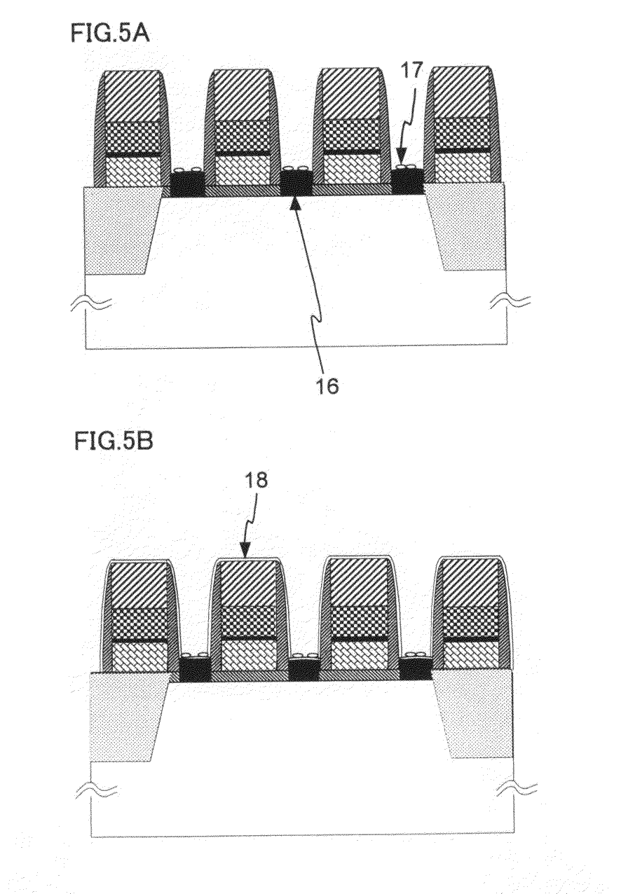

As shown in FIG. 5A, single crystalline silicon layers 16 are formed using the epitaxial growth in the regions (first and second regions positioned on the silicon substrate and in opposite sides which sandwiches the gate electrode) at which the silicon substrate is exposed. Among two single crystalline silicon layers 16 positioned in opposite sides which sandwiches the gate electrode, one single crystalline silicon layer corresponds to a first silicon layer, and the other single crystalline silicon layer corresponds to a second silicon layer. Source gas of epitaxial silicon layers 16 may be, for example, gas formed by mixing SiH₂Cl₂ gas and HCl gas and, then, diluting the mixed gas with H₂ gas. At this time, gas pressure is set to low pressure, for example, 10 Torr in the order of magnitude. Otherwise, SiH₄ gas may be used as the source gas. Meanwhile, when performing the epitaxial growth, the silicon layers containing impurities may be deposited using gas formed by mixing a gas containing impurity with the gas used for the epitaxial growth. Otherwise, after depositing, using the epitaxial growth, the silicon layers not containing the impurities, the impurities may be introduced into the deposited silicon layers in a separate step. The timing of when the impurities will be introduced into the silicon layers at the latter case is not particularly limited. For example, the impurities may be introduced into the silicon layers after deposition or after removing the foreign material on the surfaces of the silicon layers using the cleaning treatment. The impurities Concentration is set to be high (n⁺ state).

As shown in FIG. 5B, by oxidizing the surfaces of deposited silicon layers 16, oxide silicon films 18 are formed. At this time, the surfaces of the silicon nitride films also are oxidized. An oxidization method may employ an oxygen plasma treatment or a thermal oxidization method.

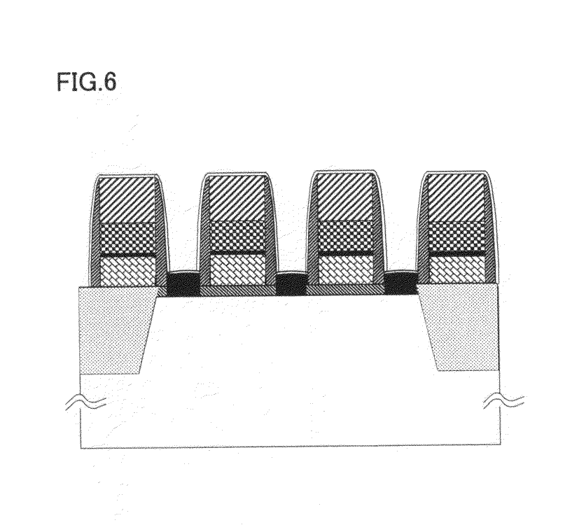

As shown in FIG. 6, foreign material 17 deposited on the surfaces of silicon layers 16 in the epitaxial growth is removed by the cleaning treatment employing pure water or chemical solution. At this time, since silicon layers 16 are protected with silicon oxide layers 18, silicon layers 16 are prevented from being dissolved by the cleaning treatment.

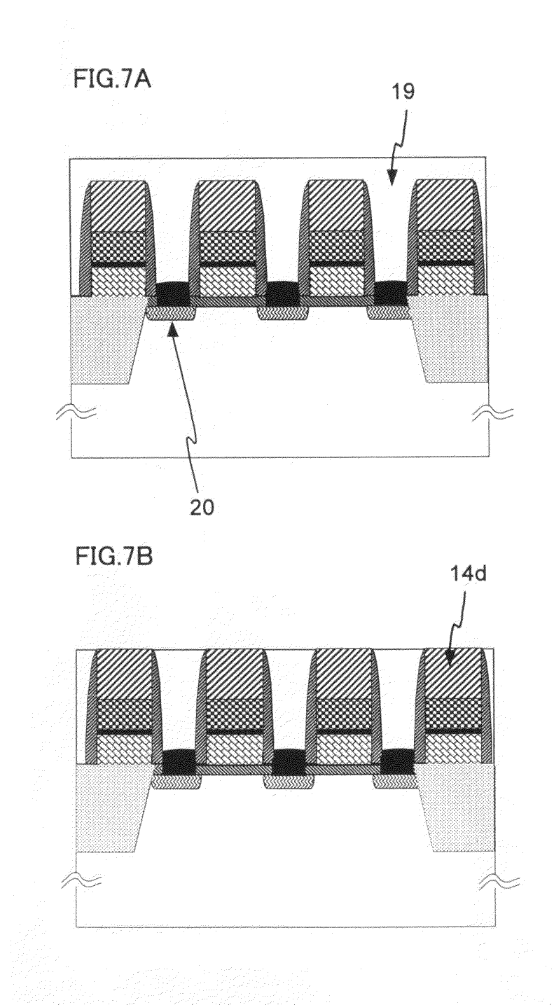

As shown in FIG. 7A, BPSG (Boron Phosphor Silicate Glass) is formed on an entire surface of the resultant structure. Then, the BPSG is converted into gate interlayer silicon oxide film 19 by performing a thermal treatment of the formed BPSG. Meanwhile, in FIG. 7A and figures following FIG. 7A, boundary between silicon oxide layer 18 and gate interlayer silicon oxide film 19 is not shown. At the same time as the thermal treatment, a thermal treatment for forming ion-implanted diffusion layers may be performed. However, such simultaneous thermal treatment is not an absolute requirement. That is, in a separate step, the thermal treatment for forming the diffusion layers may be performed. By such thermal treatment, some of the impurities with the high concentration in silicon layers 16 diffuse into the silicon substrate to form diffusion layers 20 (source or drain region) with low concentration (n⁻ state). Source region formed beneath the first silicon layer so as to be in contact with the first silicon layer corresponds to a first impurity region, and the drain region formed beneath the second silicon layer so as to be in contact with the second silicon layer corresponds to a second impurity region. In order to form such n⁻ diffusion layers 20, the impurities may be implanted after forming the gate electrode.

As shown in FIG. 7B, gate interlayer oxide silicon film 19 are subjected to a CMP treatment using silicon nitride films 14d as a stopper.

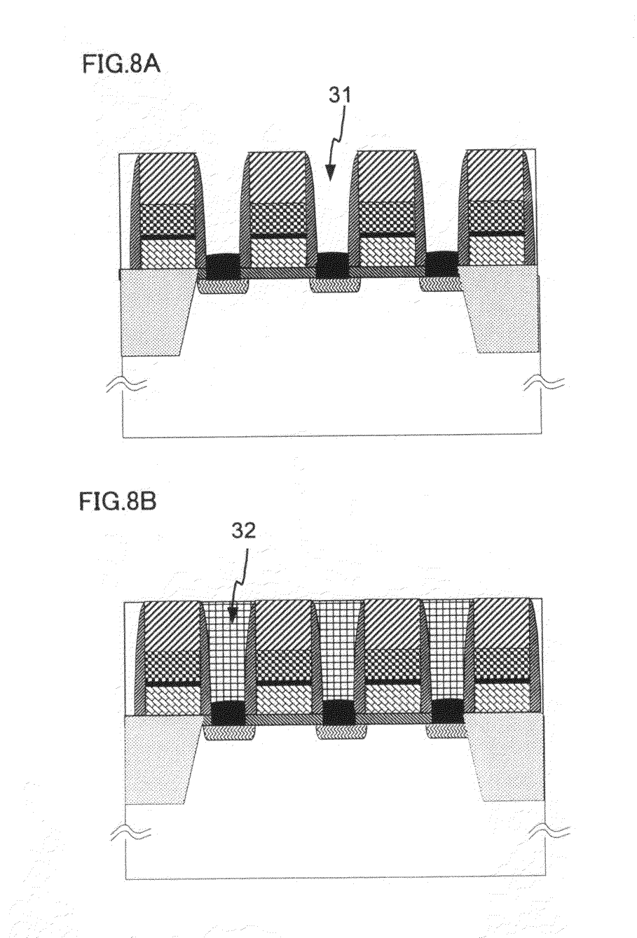

As shown in FIG. 8A, cell contact holes 31 are formed in gate interlayer oxide silicon film 19 by a SAC dry etching treatment using as a mask a resist formed by the lithography technique. Among two contact holes 31 positioned in opposite sides which sandwiches one gate electrode, one contact hole corresponds to a first contact hole, and the other contact hole corresponds to a second contact hole.

As shown in FIG. 8B, contact plugs 32 made of polysilicon, TiN, W or the like are formed in contact holes 31, and are electrically connected to overlying interconnections (not shown). In this way, the semiconductor device has been manufactured.

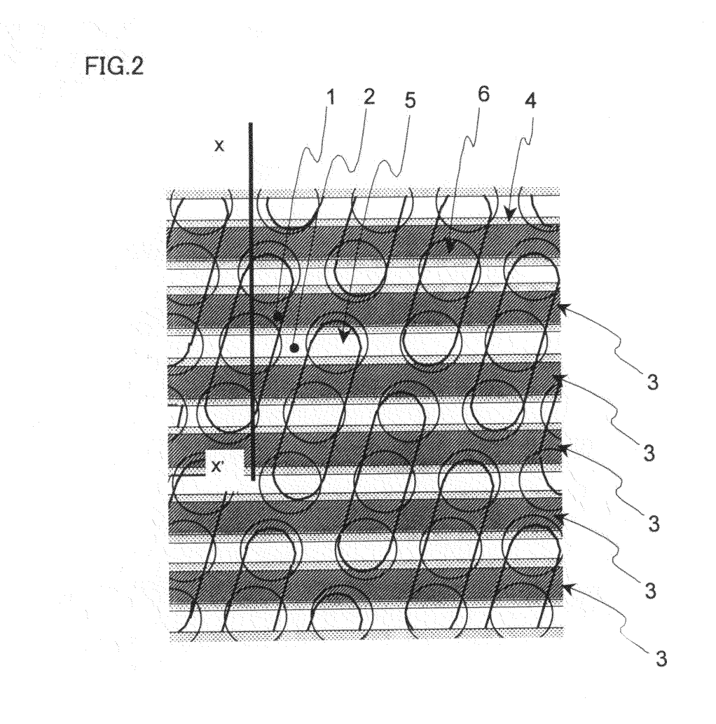

FIG. 2 is a top view of the resultant semiconductor device. FIG. 3 to FIG. 9 show cross-sectional views of the semiconductor device taken at a line X-X′ of FIG. 2. In FIG. 2, a plurality of transistor regions 1 partitioned by isolation oxide film regions 2 are provided in the silicon substrate. On each of transistor regions 1, two gate electrodes 3 with side walls 4 on the side walls thereof are provided. In the spaces on transistor regions 1 in which the gate electrodes are not formed, contact plugs 6 are formed so that silicon layers 5 are intervened between contact plugs 6 and transistor regions 1.

In this exemplary embodiment, the first and second silicon layers correspond to the elevated source and drain. The source region and the first silicon layer thereon form the source electrode. The drain region and the second silicon layer thereon form the drain electrode.

In accordance to this exemplary embodiment, the cohesive foreign material formed on the surface of silicon layer during performing the epitaxial growth can be removed using the cleaning treatment. Moreover, in the cleaning treatment, since silicon layers 16 are protected with silicon oxide layers 18, silicon layers 16 can be prevented from being dissolved. As a result, the silicon layers which have clean surface and an uniform thickness can be obtained, resulting in improving contact property between the silicon layers and the contact plugs thereon and then reducing contact resistance.

### Second Exemplary Embodiment

In the same way as in the first exemplary embodiment, the process from FIG. 3 to FIG. 7 are carried out.

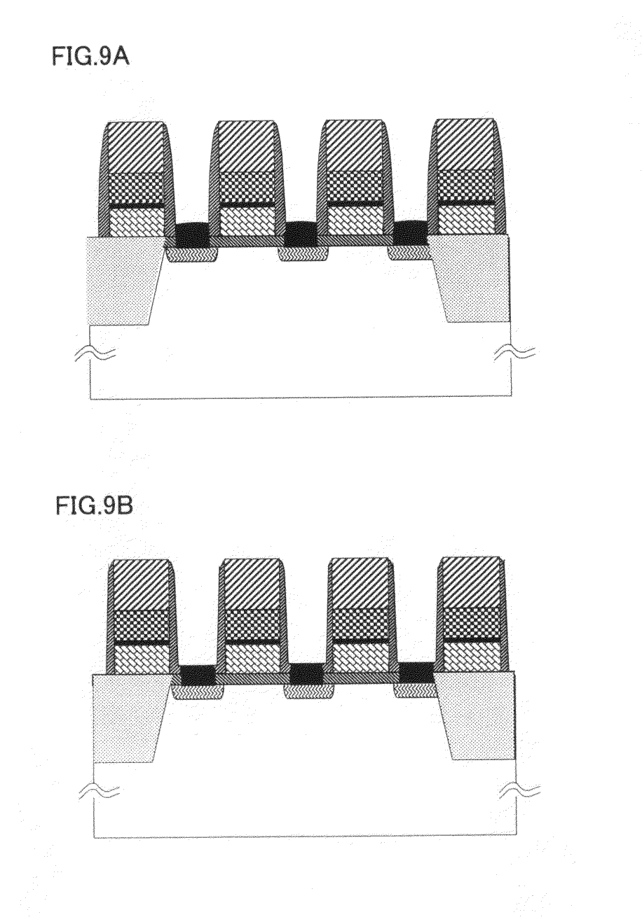

Next, as shown in FIG. 9A, oxide silicon films 18 provided for removing the foreign material deposited on the surfaces of the silicon layers are removed. To remove oxide silicon films 18, any one of light etching and wet etching methods may be employed.

As shown in FIG. 9B, first side walls 15 made of nitride silicon are etched by a wet etching so that widths of spaces between the gate electrodes become enlarged.

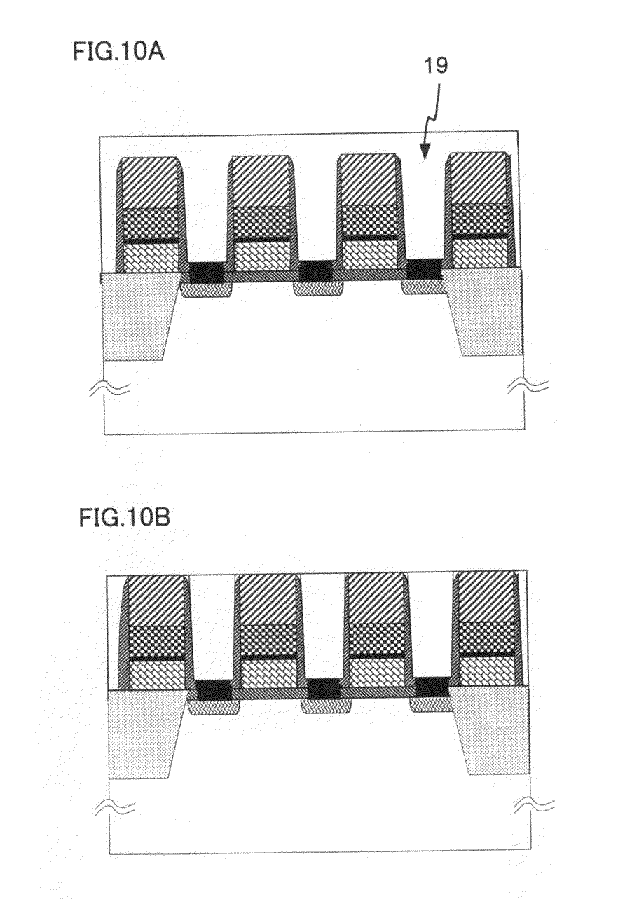

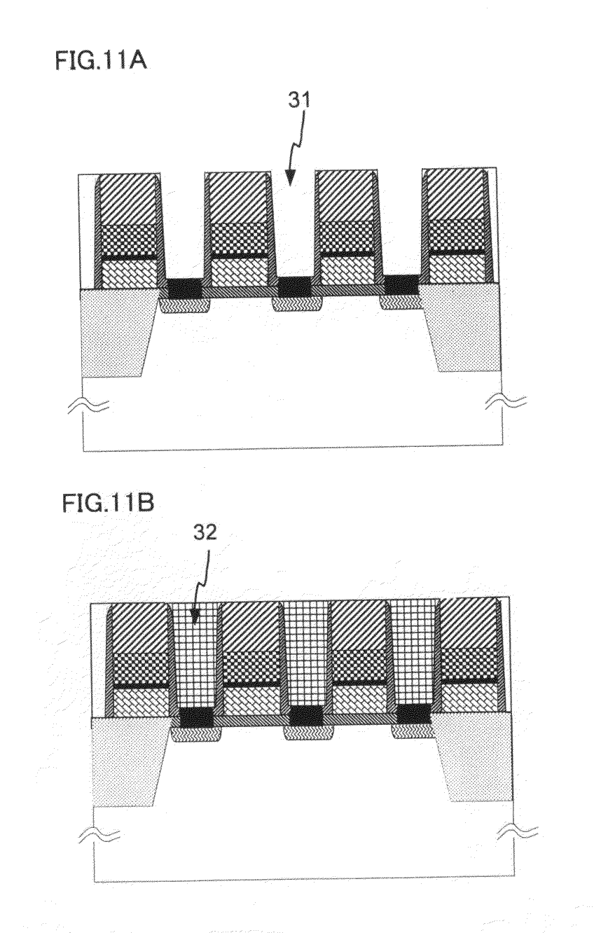

Thereafter, in the same way as in the first exemplary embodiment, gate interlayer oxide silicon film 19 is formed (FIG. 10A), and, then, formed gate interlayer oxide silicon film 19 is subjected to a CMP treatment (FIG. 10B). Subsequently, contact holes 31 are formed using the SAC dry etching (FIG. 11A), and, next, contact plugs 32 are formed in contact holes 31 (FIG. 11B). In this way, the semiconductor device has been completed.

In this exemplary embodiment, the first and second silicon layers correspond to the elevated source and drain as well.

In accordance to this exemplary embodiment, in process of FIG. 9B, since widths of spaces between the gate electrodes become enlarged, diameters of contact plugs 32 become larger as well. Consequently, it is possible to reduce cell contact resistance.

### Third Exemplary Embodiment

The first and second exemplary embodiments illustrate the examples of forming the elevated source and drain transistor by one step epitaxial growth. However, the invention is not limited thereto. For example, the invention may be applied to the method of forming the elevated source and drain transistor on the source and drain regions by two step epitaxial growth.

Below, the latter example will be described as the third exemplary embodiment. In the third exemplary embodiment, the semiconductor device may be manufactured using the same process as in the first exemplary embodiment.

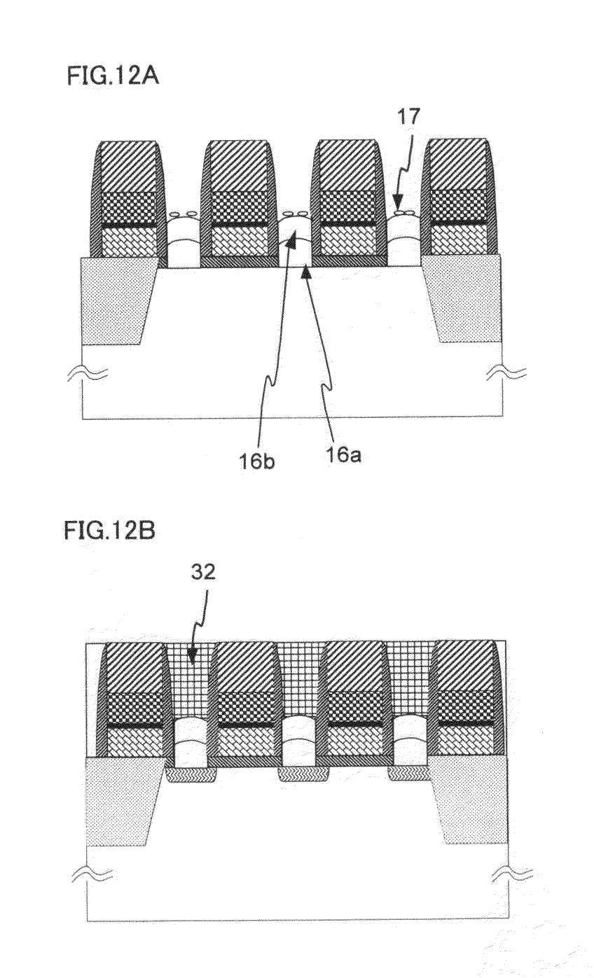

FIG. 12 shows this exemplary embodiment. As shown in FIG. 12, when performing the epitaxial growth (which corresponds to the process of FIG. 5A), the epitaxial growth includes two steps in which a first step includes forming lower silicon layers 16a and a second step includes forming upper silicon layers 16b. After forming the silicon layers, by using the same way as in the first exemplary embodiment, the semiconductor device as shown in FIG. 12B may be finally completed. In this exemplary embodiment, since the silicon layers are formed with the two steps, it is possible to considerably reduce the aspect ratio of the contact holes on source and drain electrodes. Consequently, later, when forming the contact holes on the silicon layers, the etched amount is reduced, resulting in increasing the margins for preventing short circuits between the contact plugs and the gate electrodes. Further, the finer semiconductor device may be acquired.

Furthermore, after forming the lower silicon layers and before forming the upper silicon layers, formation of the insulating film and, then, etching-back thereof may be performed. Thus, on the surfaces of the first side walls 15 above the lower silicon layers, second side walls can be formed. Consequently, short circuits between the silicon layers and the neighboring gate electrodes can be effectively avoided.

### Fourth Exemplary Embodiment

This exemplary embodiment is directed to a method for manufacturing a semiconductor device including DRAM (Dynamic Random Access Memory). Below, the example will be described as the fourth exemplary embodiment. The contact plug is formed on one of the source and drain electrodes manufactured by the method according to any one of the first to third exemplary embodiments. A bit line is formed so as to be connected to the contact plug. The contact plug is formed on the other of the source and drain electrodes. A capacitor is formed so as to be connected to the contact plug. In this way, there is formed DRAM which includes a plurality of memory cells, each memory cell comprising one capacitor and one transistor.

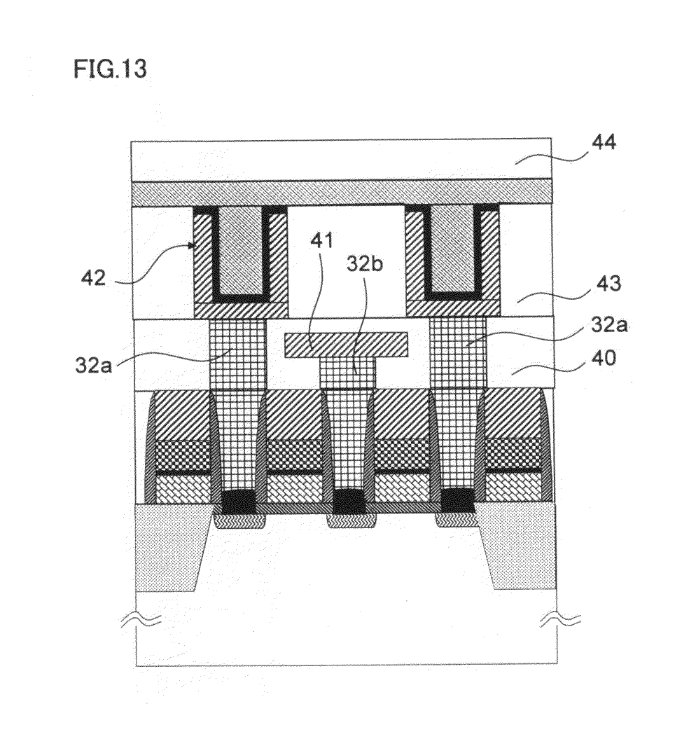

FIG. 13 shows DRAM formed by the method according to this exemplary embodiment, the DRAM including the transistor manufactured by the method according to the first exemplary embodiment. One of the source and drain electrodes is connected to bit line 41 via contact plug 32b. The other of the source and drain electrodes is connected to capacitor 42 via contact plug 32a.

It is apparent that the present invention is not limited to the above embodiments, but may be modified and changed without departing from the scope and spirit of the invention.

What is claimed is:

1. A method for forming a silicon layer, comprising:
forming a silicon layer on a silicon substrate by an epitaxial growth;
oxidizing a surface of the silicon layer; and
cleaning the surface of the silicon layer.

2. The method for forming a silicon layer according to claim 1,
wherein in oxidizing the surface of the silicon layer, at least foreign material generated on the surface of the silicon layer during the epitaxial growth is attached to an oxidized layer formed on the surface of the silicon layer, and
wherein in cleaning the surface of the silicon layer, at least the foreign material attached to the oxidized layer is removed without dissolving the silicon layer.

3. The method for forming a silicon layer according to claim 1,
wherein in oxidizing the surface of the silicon layer, the silicon layer is oxidized using an oxygen plasma treatment or a thermal oxidization treatment.

4. The method for forming a silicon layer according to claim 1,
wherein in forming the silicon layer, a gas containing impurity is mixed with a gas used for the epitaxial growth, to form the silicon layer containing impurity.

5. The method for forming a silicon layer according to claim 1, further comprising, between forming the silicon layer and oxidizing the surface of the silicon layer, implanting an impurity into the silicon layer.

6. The method for forming a silicon layer according to claim 1, further comprising, after cleaning the surface of the silicon layer, implanting an impurity into the silicon layer.

7. A method for manufacturing a semiconductor device, comprising:
forming a gate insulating film on a silicon substrate and forming a gate electrode layer including a gate electrode on the formed gate insulating film, and, then, forming a first side wall on a side wall of the gate electrode;
forming first and second silicon layers by an epitaxial growth, in first and second regions positioned in opposite sides which sandwiches the gate electrode layer and on the silicon substrate, each of the first and second silicon layers containing an impurity;
oxidizing surfaces of the first and second silicon layers;
cleaning the surfaces of the first and second silicon layers; and
forming source and drain regions in the silicon substrate so as to be in contact with the first and second silicon layers, respectively,
wherein the silicon substrate, the gate insulting film, the gate electrode, the first and second silicon layers and the source and drain regions form one transistor.

8. The method for manufacturing a semiconductor device according to claim 7,
wherein a combination of the first silicon layer and the source region forms one source electrode of the transistor, and
a combination of the second silicon layer and the drain region forms one drain electrode of the transistor.

9. The method for manufacturing a semiconductor device according to claim 7,
wherein in forming the first and second silicon layers containing the impurity, a gas containing impurity is mixed with a gas used for the epitaxial growth, to form the first and second silicon layers containing impurity.

10. The method for manufacturing a semiconductor device according to claim 7,
wherein in place of forming the first and second silicon layers containing the impurity, forming first and second silicon layers by an epitaxial growth, in the first and second regions on the silicon substrate, each of the first and second silicon layers not containing an impurity, and
the method further comprises implanting an impurity in the first and second silicon layers, between forming the first and second silicon layers not containing an impurity and oxidizing the surfaces of the first and second silicon layers.

11. The method for manufacturing a semiconductor device according to claim 7,
wherein in place of forming the first and second silicon layers containing the impurity, forming first and second silicon layers by an epitaxial growth, in the first and second regions on the silicon substrate, each of the first and second silicon layers not containing an impurity, and
the method further comprises implanting an impurity in the first and second silicon layers, after cleaning the surfaces of the first and second silicon layers.

12. The method for manufacturing a semiconductor device according to claim 7,
wherein in forming the source and drain regions, the source and drain regions are formed by diffusing the impurity contained in the first and second silicon layers into the silicon substrate using a thermal treatment.

13. The method for manufacturing a semiconductor device according to claim 7,
wherein in forming the source and drain regions, the source and drain regions are formed by implanting an impurity into the silicon substrate using at least the gate electrode as a mask, after forming the gate electrode layer.

14. The method for manufacturing a semiconductor device according to claim 7, further comprising:
forming a first insulating film at least on the gate electrode layer and the first and second silicon layers;
forming first and second contact holes in the first insulating film so as to expose the first and second silicon layers, respectively; and
forming first and second contact plugs in the first and second contact holes, respectively,
wherein the first and second contact plugs are electrically connected to the first and second silicon layers, respectively.

15. The method for manufacturing a semiconductor device according to claim 14, further comprising:
between forming the first insulating film and forming the first and second contact holes, polishing the first insulating film using the gate electrode layer as a stopper.

16. The method for manufacturing a semiconductor device according to claim 7, further comprising:
between oxidizing the surfaces of the first and second silicon layers and forming the source and drain regions, removing silicon oxide layers formed by oxidizing the surfaces of the first and second silicon layers.

17. The method for manufacturing a semiconductor device according to claim 14, further comprising enlarging diameters of the first and second contact holes by etching the first side wall, between forming the first and second contact holes and forming the first and second contact plugs.

18. The method for manufacturing a semiconductor device according to claim 7,
wherein the step of forming the first and second silicon layers comprises:
forming two lower silicon layers in the first and second regions on the silicon substrate;
oxidizing surfaces of the two lower silicon layers;
removing silicon oxide layers formed by oxidizing the surfaces of the two lower silicon layers; and
further forming two upper silicon layers on the two lower silicon layers, respectively, to form the first and second silicon layers, each of the first and second silicon layers containing the lower and upper silicon layers.

19. The method for manufacturing a semiconductor device according to claim 18,
wherein in forming the first and second silicon layers, after forming the two lower silicon layers and before forming the two upper silicon layers, a second side wall further is formed on surface of the first side wall by forming a second insulating film at least in the first and second regions, and, then etching-back the second insulating film.

20. The method for manufacturing a semiconductor device according to claim 7, further comprising:
forming a first insulating film at least on the gate electrode layer and the first and second silicon layers;
forming first and second contact holes in the first insulating film so as to expose the first and second silicon layers, respectively;
forming first and second contact plugs in the first and second contact holes, respectively;
forming a bit line so as to be electrically connected to the first contact plug; and
forming a capacitor so as to be electrically connected to the second contact plug.
